(19) United States
(12) Patent Application Publication
(10) Pub. No.: US 2023/0420541 A1
(43) Pub. Date: Dec. 28, 2023

(54) MULTI-THRESHOLD VOLTAGE GALIUM NITRIDE HIGH ELECTRON MOBILITY TRANSISTOR

(71) Applicant: NATIONAL RESEARCH COUNCIL OF CANADA, Ottawa (CA)

(72) Inventors: Alireza LOGHMANY, Kanata (CA); Elias AL ALAM, Gloucester (CA)

(21) Appl. No.: 18/252,968

(22) PCT Filed: Nov. 2, 2021
(86) PCT No.: PCT/IB2021/060138

§ 371 Date: May 15, 2023

Related U.S. Application Data
(60) Provisional application No. 63/114,203, filed on Nov. 16, 2020.

(51) Int. Cl. H01L 29/66; H01L 29/778; H01L 29/423

(52) U.S. Cl. CPC H01L 29/66462; H01L 29/7786; H01L 29/4236; H01L 29/2003

(57) ABSTRACT

A device and method of fabricating a device having a plurality of depletion-mode high-electron-mobility transistors (HEMTs) on a single wafer are disclosed. The method of fabrication involves providing semiconductor layers capable of sustaining a two-dimensional electron sheet to enable electrical current to flow through the HEMT, forming a series of trenches and fins in the semiconductor layers over an active area of the semiconductor layers on which a gate contact terminal is to be set down, the fins of respective HEMTs having different widths resulting in different voltage thresholds for the respective depletion-mode HEMTs.

### FIELD

The present specification relates to high-electron-mobility transistors (HEMTs), and more particularly to a multi-threshold voltage AlGaN/GaN high-electron-mobility transistor (HEMT) and method of fabricating a multi-threshold voltage AlGaN/GaN HEMT.

### BACKGROUND

A high-electron-mobility transistor (HEMT), also known as a heterostructure FET (HFET), includes a source contact terminal, a drain contact terminal, and a gate contact terminal to which a voltage may be applied to control the flow of electrical current between the source contact terminal and the drain contact terminal. Unlike, CMOS transistors, where current flows through a doped channel region, HEMTs incorporate a junction between two materials with different band gaps (i.e. a heterojunction) as the current flow channel. A HEMT may be either a depletion-mode HEMT, which is normally in an “on” state at zero gate-source voltage, or an enhancement-mode HEMT, which is normally in an “off” state at zero gate-source voltage.

HEMTs may be designed to have a high breakdown voltage, high peak electron drift velocity, and high concentration of two-dimensional electron gas. Such characteristics may be provided by semiconductor layers made of aluminum gallium nitride (AlGaN) and gallium nitride (GaN) which create a sheet of two-dimensional electron gases (2DEG) by positive polarization induced interface charges (spontaneous and piezoelectric polarization). The formation of two-dimensional electron gases in AlGaN/GaN heterostructures rely on the difference of the polarization between the AlGaN and the GaN layers.

There is a strong relationship between the concentration of the 2DEG sheet, concentration of Al and thickness of the AlGaN layer (as well as the type of metal used for the Schottky layer of the tri-gate structure, where the gate wraps around a raised source-to-drain channel instead of residing on top of the channel in the traditional 2D planar design). Therefore, a fabricated AlGaN/GaN HEMT with a given concentration of Al and thickness of the AlGaN layer will exhibit a particular threshold voltage.

In various applications, it is desirable to provide component transistors on a circuit that are characterized by different threshold voltages (known as Multi-Threshold Voltage (MThV) transistors). For example, lower threshold voltage depletion-mode transistors may be used as load “resistors” for the logic portion of a circuit and higher threshold voltage enhancement-mode transistors may be used as switching elements for the SRAM portion of the circuit.

Fabrication of multi-threshold transistors is possible with silicon-based technology, such as CMOS, by varying the channel doping. However, this technique is not applicable when fabricating HEMT devices since there is no doped channel in an HEMT transistor.

### SUMMARY

According to an aspect of the specification, a method for fabricating a AlGaN/GaN high-electron-mobility transistor (HEMT) is set forth, the method comprising: providing semiconductor layers capable of sustaining a two-dimensional electron sheet to enable electrical current to flow through the HEMT, wherein the semiconductor layers comprise a first layer of aluminum gallium nitride (AlGaN) and a second layer of gallium nitride (GaN), whereby the concentration of Al and thickness of AlGaN give rise to a characteristic threshold voltage; forming a series of trenches and fins in the semiconductor layers in an active area of the semiconductor layers on which gate contact terminals are to be set down, wherein the width of the fins is chosen to shift the characteristic threshold voltage to a new threshold voltage, and wherein the new threshold voltage increases with reduction in the width of the fins; and setting down gate contact terminals across the fins at the active area.

According to another aspect of the specification, a method of fabricating a wafer containing a plurality of high-electron-mobility transistors (HEMTs) is set forth, the method comprising: providing semiconductor layers capable of sustaining a two-dimensional electron sheet to enable electrical current to flow through the HEMTs, wherein the semiconductor layers comprise a first layer of aluminum gallium nitride (AlGaN) and a second layer of gallium nitride (GaN), whereby the concentration of Al and thickness of AlGaN give rise to a characteristic threshold voltage; for a first one of said HEMTs: forming a series of first trenches and first fins in the semiconductor layers over a first active area of the semiconductor layers on which a first gate contact terminal of the first one of said HEMTs is to be set down, wherein the width of the first fins is chosen to shift the characteristic threshold voltage to a new threshold voltage; setting down the first gate contact terminal across the first fins; and setting down a first source contact terminal and a first drain contact terminal on either side of the first gate contact terminal outside of the first active area; and for a further one of said HEMTs: forming a series of further trenches and further fins in the semiconductor layers over a further active area of the semiconductor layers on which a further gate contact terminal of the HEMT is to be set down, wherein the width of the further fins is less than the width of the first fins to shift the characteristic threshold voltage below the new threshold voltage first one of said HEMTs; setting down a further gate contact terminal across the further series of fins; and setting down a further source contact terminal and a further drain contact terminal on either side of the further gate contact terminal outside of the further active area.

According to a further aspect of the specification, there is provided a device comprising: semiconductor layers comprising a first layer of aluminum gallium nitride (AlGaN) and a second layer of gallium nitride (GaN), said layers being capable of sustaining a two-dimensional electron sheet to enable electrical current to flow, the semiconductor layers comprising a plurality of active areas on which gate contact terminals are to be set down, the active areas comprising a series of trenches and fins, the fins having different widths over each active area; a plurality of drain contact terminals adjacent respective ones of the active areas; a plurality of source contact terminals adjacent respective ones of the active areas; and a plurality of gate contact terminals set down across the fins of respective ones of the active areas, such that the device comprises a plurality of AlGaN/GaN high-electron-mobility transistors (HEMTs) having different threshold voltages.

### BRIEF DESCRIPTION OF THE DRAWINGS

FIG. 1 is a schematic diagram of a cross-section of an example high-electron-mobility transistor (HEMT) with a gate contact terminal set down over a series of trenches and small fins.

FIG. 2A is a perspective view of the HEMT of FIG. 1.

FIG. 2B is a close-up perspective view of a portion of the trenches and fins shown in FIG. 2A.

FIG. 3 is a flowchart of an example method to fabricate a gate contact terminal set down over small fin features for a HEMT.

FIG. 4A a schematic diagram of a first stage of fabrication of an example of a gate contact terminal set down over small fin features, prior to dry etching of the trenches for a HEMT.

FIG. 4B is a schematic diagram of a second stage of fabrication of the active area of FIG. 4A with the fins dry etched into the semiconductor layers.

FIG. 4C is a schematic diagram of a third stage of fabrication of the active area of FIG. 4A with a gate contact terminal set down over the fins.

FIG. 5 is a flowchart of an example method to form multiple AlGaN/GaN HEMTs having different threshold voltages on a single wafer.

FIG. 6 is a plan view of a circuit having multiple AlGaN/GaN HEMTs having different threshold voltages formed according to the method of FIG. 5.

FIG. 7 is a graph showing shift in threshold voltage of a AlGaN/GaN HEMT with change of fin width.

### DETAILED DESCRIPTION

Prior art approaches to fabricating multi-threshold voltage AlGaN/GaN HEMTs include techniques such as barrier-thinning and fluoride-based plasma treatment, among others. However, barrier-thinning and fluoride-based plasma treatment techniques may result in high gate-leakage current and the possibility of hysteresis in the gate characteristics of AlGaN/GaN HEMTs due to surface damage and ease of tunneling through the thinned-barrier in the case of barrier-thinning and/or by movement of fluorine ions, in the case of fluoride-based plasma treatment. In addition to these drawbacks, the barrier-thinning technique is neither reliable nor repeatable since etch control in the range of nanometers is required. Fluoride-based plasma treatment also usually has inconstant and unexpected results, especially for high temperature applications.

Described herein are methods to fabricate multi-threshold voltage AlGAN/GaN HEMTs with tri-gate structure set down within an active area corrugated with small fins separated by trenches etched in the active area. The methods involve modifying the width of the fins and thereby the concentration of the two-dimensional electron sheet without requiring significant additional fabrication steps or damage to the top surface of the transistors. In some aspects, the fin width can vary from 30-500 nanometers. Such small fin feature sizes may be realized using electron beam lithography and inductively coupled plasma-reactive ion etching (ICP-RIE). Thus, for a fabricated AlGaN/GaN HEMT with a given concentration of Al and thickness of the AlGaN layer, the threshold voltage can be varied by varying the fin width. For example, if the fabricated AlGaN/GaN HEMT is characterized by an intrinsic threshold voltage (e.g. V_{TH}=−3V), etching mesas in the active are to create small fins, the threshold voltage can be shifted (e.g. to V_{TH}=−1V). Moreover, multiple HEMTs with different threshold voltages can be fabricated on a single wafer by varying the width of the fins.

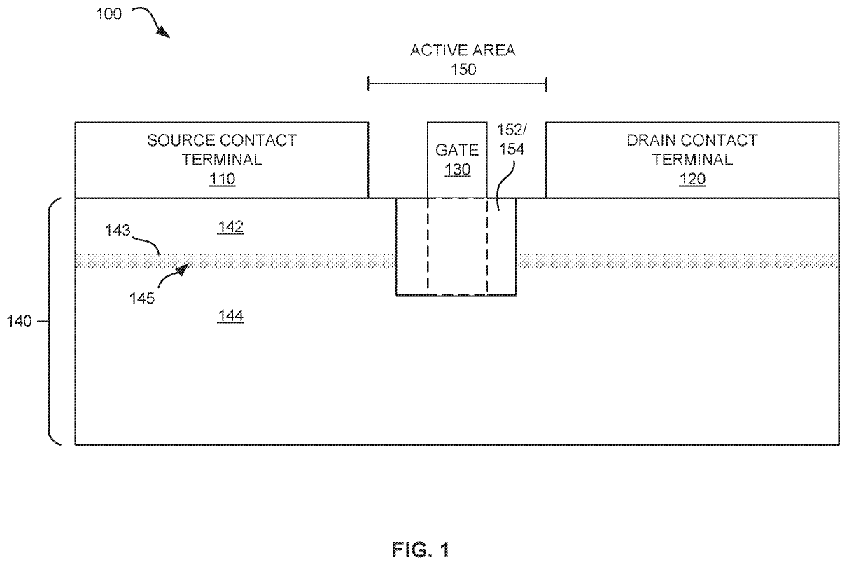

FIG. 1 is a schematic diagram of a cross-section of an example high-electron-mobility transistor (HEMT) 100. The HEMT 100 includes a source contact terminal 110, a drain contact terminal 120, and a gate contact terminal 130. The source contact terminal 110, drain contact terminal 120, and gate contact terminal 130 are metal conductors.

The HEMT 100 further includes semiconductor layers 140 capable of sustaining a two-dimensional electron sheet to enable electrical current to flow through the HEMT 100. The two-dimensional electron sheet comprises a two-dimensional electron gas (2DEG), which is an electron gas that is free to move in two dimensions, but tightly confined in the third dimension. The semiconductor layers 140 comprise a first semiconductor layer, or barrier 142, of a first semiconductor material, and a second semiconductor layer, or channel 144, of a second semiconductor material underneath the barrier 142. The barrier 142 and channel 144 form layers that run continuously beneath the source contact terminal 110 and drain contact terminal 120 (the continuous path is not shown in the cross-section of FIG. 1, because it is out of the plane). The gate contact terminal 130 is set down within an active area 150 some of which is corrugated with small fins 154 and trenches 152, as discussed in greater detail below.

The second semiconductor material has a different band gap than the first semiconductor material, and thus a heterointerface 143 is formed between the barrier 142 and the channel 144. The channel 144 includes a region in which a two-dimensional electron sheet is formed, referred to herein as the two-dimensional electron sheet region 145. The two-dimensional electron sheet region 145 is in the channel 144 and adjacent to the heterointerface 143. The thickness of the two-dimensional electron sheet region 145 is exaggerated in the Figures for illustrative purposes, but it is to be understood that the thickness of the two-dimensional electron sheet region 145 may have a thickness of only about 1-2 nanometers. Further, it is to be understood that the channel 144 is an upper portion of a deeper layer of the second semiconductor material, below which may include the substrate wafer and any additional layer(s) epitaxially grown (not shown in FIG. 1) to accommodate lattice mismatch between the substrate wafer and the channel 144.

The second semiconductor material is selected to serve as a HEMT channel and the first semiconductor material is selected to serve as a HEMT barrier compatible with the channel. In the present example, the first semiconductor material includes aluminum gallium nitride (AlGaN) and the second semiconductor material may include gallium nitride (GaN).

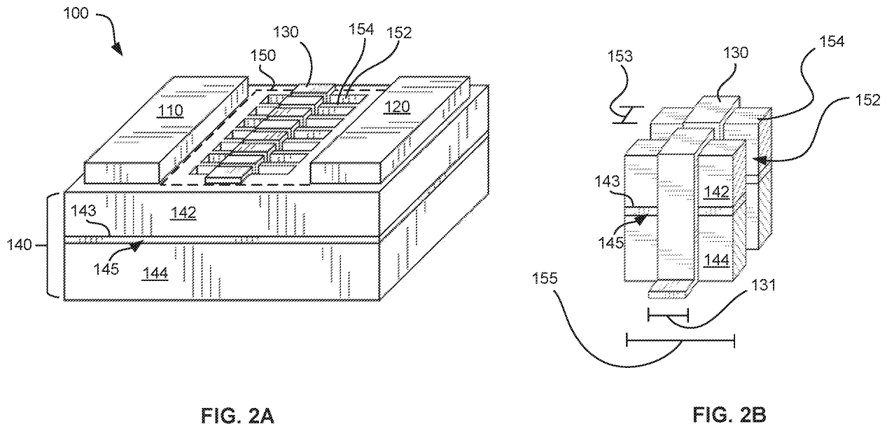

As mentioned above, the semiconductor layers 140 include the active area 150 on which a gate contact terminal 130 is to be set. The active area 150 includes a series of fins 154 having widths 153 (See FIG. 2B) of about 30 to 500 nanometers. In other words, each of the fins 154 spans a width 153 of from about 30 to 500 nanometers across. The fins 154 are separated by trenches 152 of the etched portions of the semiconductor layer 140 between the fins 154. FIGS. 2A and 2B provide perspective views of the HEMT 100 and the trenches 152 and fins 154. The active area 150 spans from an edge of the source contact terminal 110 to an edge of the drain contact terminal 120. The gate contact terminal 130 has a gate width 131. Further, the fins 154 have lengths 155 that can be equal to, less than, or larger than the gate width 131.

The gate contact terminal 130 is set down across the fins 154. The trenches 152 and fins 154 run perpendicular to the direction of the gate contact terminal 130, as shown in FIGS. 2A and 2B. The gate contact terminal 130 is situated between the source contact terminal 110 and drain contact terminal 120.

Some segments of the gate contact terminal 130 rest on top of the barrier 142 or on a thin insulator layer (the latter not shown), forming either a Schottky contact or metal-insulator-semiconductor structure. Further, some segments of the gate contact terminal 130 that run down the trenches 152 rest adjacent to the inner side walls of the trenches 152, which may be of the barrier 142 or the channel 144. Further, some segments of the gate contact terminal 130 rest on the bottoms of the trenches 152 in the channel 144.

The trenches 152 extend through the semiconductor layer 140 past a depth at which the two-dimensional electron sheet is to be formed, or in other words, past the two-dimensional electron sheet region 145. Thus, in some examples, the trenches 152 may extend about 40 nanometers into the semiconductor layer 140, depending on the depth of the heterointerface 143.

As mentioned previously, the widths 153 of the fins 154 are between 30 nm to 500 nm.

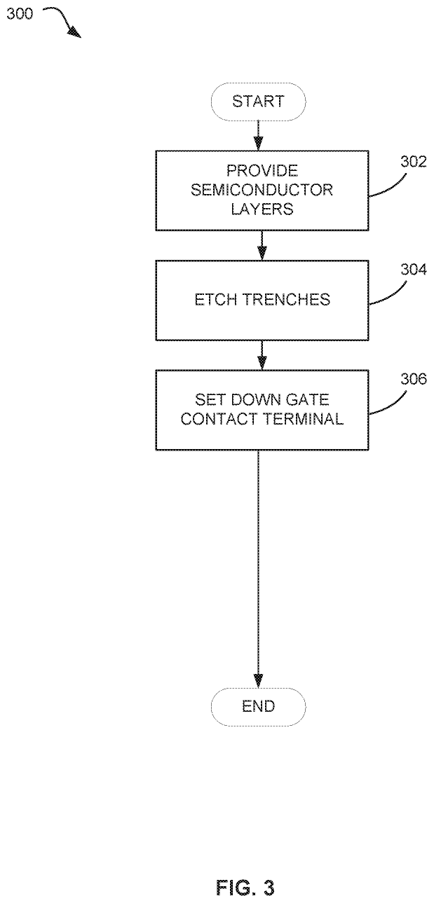

FIG. 3 is a flowchart of an example method 300 to fabricate a gate contact terminal set down over small fins for a HEMT, which may be similar to the HEMT 100 of FIG. 1.

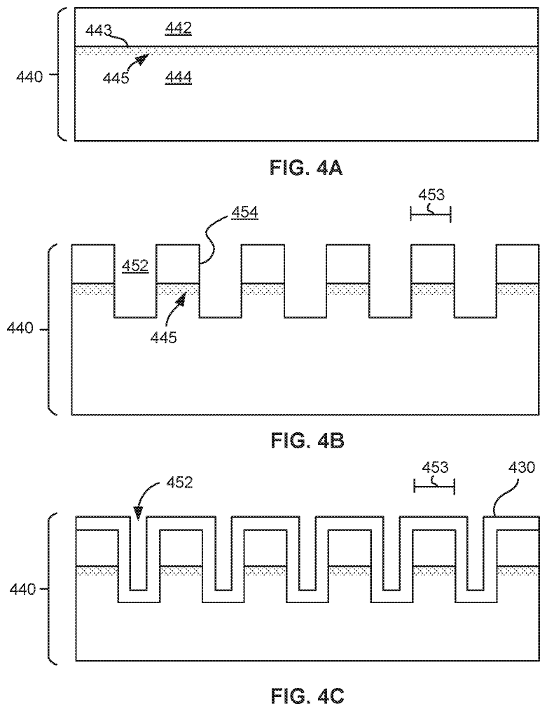

At block 302, semiconductor layers capable of sustaining a two-dimensional electron sheet to enable electrical current to flow through the HEMT are provided. The semiconductor layers may be similar to the semiconductor layers 142 and 144 of semiconductor layers 140 of FIG. 1, and thus for further description of such semiconductor layers, reference to the semiconductor layers 140 of FIG. 1 may be had. An example of semiconductor layers 440 is shown in FIG. 4A, including a barrier 442, channel 444, heterointerface 443, and two-dimensional electron sheet region 445.

Returning to FIG. 3, at block 304, a series of trenches in the semiconductor layer are etched within an active area of the semiconductor layer to create a series of fins on which a gate contact terminal is to be set down. The fins which have widths of from about 30 nm to 500 nm across, and are separated by trenches. Such fins may be similar to the fins 154 of FIG. 2B, and thus for further description of such trenches, reference to the trenches 152 of FIG. 2B may be had.

An example of semiconductor layers 440 with such trenches formed therein is shown in FIG. 4B as trenches 452 spaced apart by fins 454. In FIG. 4B, it can be seen that the trenches 452 extend through the semiconductor 440 layer past a depth at which the two-dimensional electron sheet is to be formed, or in other words, past the two-dimensional electron sheet region 445.

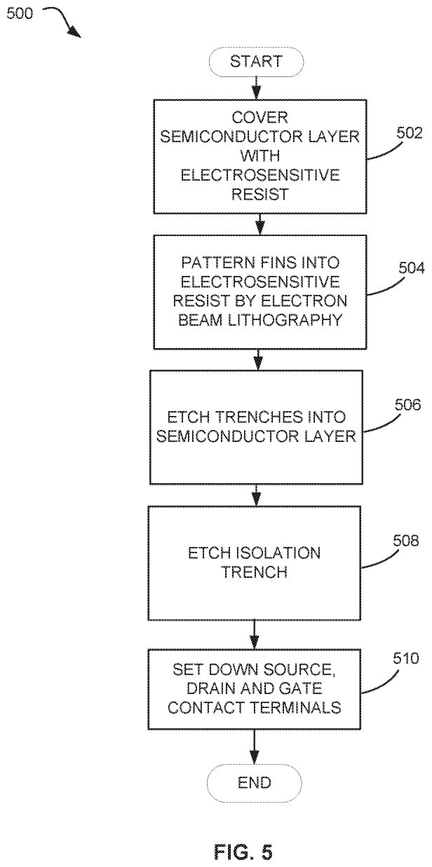

The trenches 452 may be formed in the semiconductor layer 440 by a combination of electron beam lithography and dry etching, as described in greater detail in FIG. 5, below.

Returning to FIG. 3, at block 306, a gate contact terminal is set down across the fins. The gate contact terminal may be similar to the gate contact terminal 130 of FIG. 1, and thus for further description of such a gate contact terminal, reference to the gate contact terminal 130 of FIG. 1 may be had.

An example of semiconductor layers 440 with trenches 452 and fins 454 formed therein and a gate contact terminal 430 set down across the fins 454 is shown in FIG. 4C. In FIG. 4C, it can be seen that the gate contact terminal 430 is set down perpendicular to the trenches 452 and fins 454.

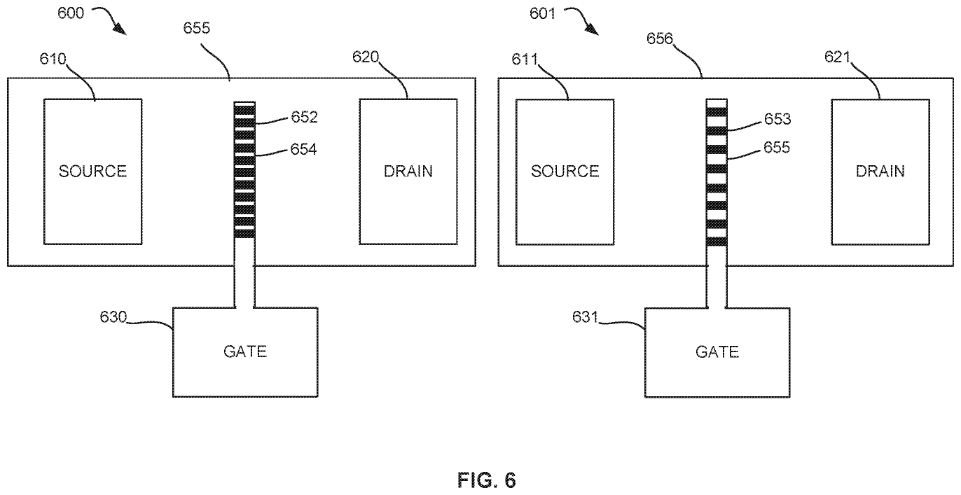

FIG. 5 is a flowchart of an example method 500 to form multiple AlGaN/GaN HEMTs 600 and 601 with different threshold voltages, such as shown in FIG. 6. At block 502, semiconductor layers equivalent to layers 440 shown in FIG. 4, are covered with an electrosensitive resist layer. The electrosensitive resist layer may include hydrogen silsesquioxane (HSQ).

At block 504, a series of fins are patterned using the electrosensitive resist layer by electron beam lithography, thereby forming a mask from the electrosensitive resist layer. The HSQ that is exposed to the electron beam of a sufficient dose is converted into silicon oxide. The unexposed HSQ can be removed as waste by an intermediate development step. The HSQ is a high-resolution resist that is particularly well-suited for this application since the exposed resist provides a suitable mask for subsequent plasma etching of the semiconductor layer. A typical polymer resist layer may not withstand the subsequent plasma etching, and alternatively, the use of a sacrificial hard mask may introduce complexity and risk of damaging the semiconductor layers.

At block 506, the series of trenches is dry etched into the semiconductor layer through the mask. The trenches may be dry etched with chlorine-based dry etching and by inductively coupled plasma-reactive ion etching (ICP-RIE). Thus, small isolation features in the form of small fins spaced part by trenches may be fabricated, with the fins having widths equal to or less than about 30 nm and as great as 300 nm.

According to an aspect of the invention, the width of the patterned fins 654 between trenches 652 of HEMT 600 at block 504 are different than the width of the fins 655 between trenches 653 of HEMT 601, resulting in different threshold voltages (V_{TH}) of the transistors 600 and 601, formed in parallel on a single wafer. Further isolation trenches 655 and 656 are etched for electrically isolating HEMTs 600 and 601. At block 510, metal contact terminals are set down for sources 610 and 611, drains 620 and 621 and gates 630 and 631. The gate contact terminals 630 and 631 are set down across the fins 654 and 655. The trenches 652, 653 and fins 654,655 run perpendicular to the direction of the gate contact terminals 630, 631, as shown in FIG. 6. The gate contact terminals 630, 631 are situated between the source contact terminals 610, 611 and drain contact terminals 620, 621.

Thus, as shown in the plan view of FIG. 6, example AlGaN/GaN high-electron-mobility transistors (HEMTs) 600 and 601 include source contact terminals 610 and 611, drain contact terminals 620 and 621, and gate contact terminals 630 and 631, deposited on underlying semiconductor layers to enable electrical current to flow through the HEMTs 600 and 601 when the respective threshold voltages (V_{TH}) for HEMTs 600 and 601 are exceeded. In other words, HEMTs 600 and 601 turn on at different threshold voltages dependent on the width of the fins 654 and 655, respectively, wherein the width of the fins in HEMT 600 is less than the width of the fins in HEMT resulting in a higher threshold voltage than HEMT 601.

If the width of the fins 654 in HEMT 600 is made small enough (e.g. 30 nm), or the fins 654 are eliminated entirely, HEMT 600 becomes an enhancement mode device.

The method of FIG. 5 results in parallel processing AlGaN/GaN HEMTs with different threshold voltages without adding any major step to the fabrication process (e.g. no additional mask) or additional damage to the top-surface of the device. AlGaN/GaN HEMTs fabricated according to the method of FIG. 5 can yield fin widths in the range of 30 nm to 500 nm.

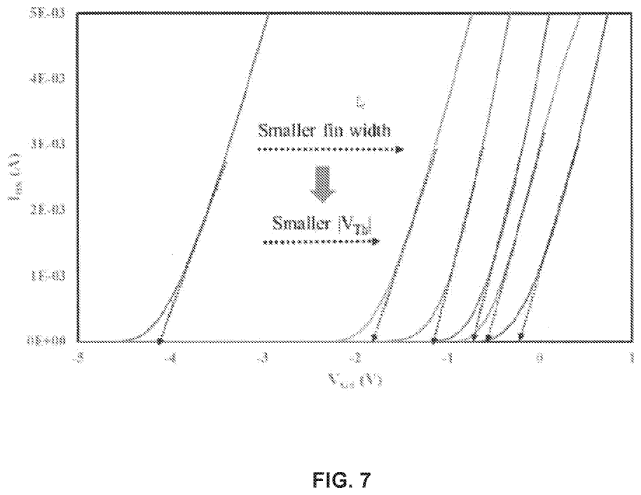

FIG. 7 shows the shift in threshold voltage (V_{TH}) for AlGaN/GaN HEMTs with change in fin width. As can be seen, small fin widths result in higher V_{TH}, due to the strain relaxation and depletion of the two-dimensional electron gas sheet due to Schottky barrier

Thus, as described herein, a plurality of HEMTs having different threshold voltages may be produced on a single wafer. Such HEMTs may be produced with small fin isolation features and without the need for a separate sacrificial mask, thereby minimizing the risk of damage to the surface of the semiconductor layers. Such reliable HEMTs may be applicable in radio frequency (RF), power electronics, and digital applications, and may be particularly useful in extreme temperature and harsh environments such as automotive and aerospace engine controls, well logging in petroleum exploration, and nuclear reactors, due to the fact that GaN-based devices have fundamental advantages over conventional Si and GaAs devices for high-temperature operations.

It should be recognized that features and aspects of the various examples provided above can be combined into further examples that also fall within the scope of the present disclosure. The scope of the claims should not be limited by the above examples but should be given the broadest interpretation consistent with the description as a whole.

1. A method for fabricating a AlGaN/GaN high-electron-mobility transistor (HEMT), the method comprising:
providing semiconductor layers capable of sustaining a two-dimensional electron sheet to enable electrical current to flow through the HEMT, wherein the semiconductor layers comprise a first layer of aluminum gallium nitride (AlGaN) and a second layer of gallium nitride (GaN), whereby the concentration of Al and thickness of AlGaN give rise to a characteristic threshold voltage;
forming a series of trenches and fins in the semiconductor layers in an active area of the semiconductor layers on which gate contact terminals are to be set down, wherein the width of the fins is chosen to shift the characteristic threshold voltage to a new threshold voltage, and wherein the new threshold voltage increases with reduction in the width of the fins; and
setting down gate contact terminals across the fins at the active area.

2. The method of claim 1, wherein forming the series of trenches and fins comprises:
covering the semiconductor layers with an electrosensitive resist layer;
patterning the fins into the electrosensitive resist layer by electron beam lithography to form a mask; and
dry etching the trenches into the semiconductor layers through the mask.

3. The method of claim 2, wherein dry etching the series of trenches into the semiconductor layers comprises inductively coupled plasma-reactive ion etching (ICP-RIE).

4. The method of claim 2, wherein the electrosensitive resist layer comprises hydrogen silsesquioxane (HSQ).

5. The method of claim 1, wherein the gate contact terminals are set down perpendicular to the fins.

6. The method of claim 1, wherein the trenches extend through the semiconductor layers past a depth at which the two-dimensional electron sheet is to be formed.

7. The method of claim 1, wherein the width of the fins is chosen to shift the characteristic threshold voltage to a voltage that is sufficient for creating a depletion mode HEMT.

8. The method of claim 1, wherein the width of each of the fins is from about 30 nm to 500 nm across.

9. A method of fabricating a wafer containing a plurality of high-electron-mobility transistors (HEMTs), the method comprising:
providing semiconductor layers capable of sustaining a two-dimensional electron sheet to enable electrical current to flow through the HEMTs, wherein the semiconductor layers comprise a first layer of aluminum gallium nitride (AlGaN) and a second layer of gallium nitride (GaN), whereby the concentration of Al and thickness of AlGaN give rise to a characteristic threshold voltage;
for a first one of said HEMTs:
forming a series of first trenches and first fins in the semiconductor layers over a first active area of the semiconductor layers on which a first gate contact terminal of the first one of said HEMTs is to be set down, wherein the width of the first fins is chosen to shift the characteristic threshold voltage to a new threshold voltage;
setting down the first gate contact terminal across the first fins; and
setting down a first source contact terminal and a first drain contact terminal on either side of the first gate contact terminal outside of the first active area; and
for a further one of said HEMTs:
forming a series of further trenches and further fins in the semiconductor layers over a further active area of the semiconductor layers on which a further gate contact terminal of the HEMT is to be set down, wherein the width of the further fins is less than the width of the first fins to shift the characteristic threshold voltage below the new threshold voltage first one of said HEMTs;
setting down a further gate contact terminal across the further series of fins; and
setting down a further source contact terminal and a further drain contact terminal on either side of the further gate contact terminal outside of the further active area.

10. The method of claim 9, wherein forming the series of trenches and fins comprises:
covering the semiconductor layers with an electrosensitive resist layer;
patterning the fins into the electrosensitive resist layer by electron beam lithography to form a mask; and
dry etching the trenches into the semiconductor layers through the mask.

11. The method of claim 10, wherein dry etching the series of trenches into the semiconductor layers comprises inductively coupled plasma-reactive ion etching (ICP-RIE).

12. The method of claim 10, wherein the electrosensitive resist layer comprises hydrogen silsesquioxane (HSQ).

13. The method of claim 9, wherein the gate contact terminals are set down perpendicular to the fins.

14. The method of claim 9, wherein the trenches extend through the semiconductor layers past a depth at which the two-dimensional electron sheet is to be formed.

15. The method of claim 9, wherein the width of the fins is chosen to shift the characteristic threshold voltage to a voltage that is sufficient for creating a depletion mode HEMT.

16. The method of claim 9, wherein the width of each of the fins is from about 30 nm to 500 nm across.

17. A device comprising:
semiconductor layers comprising a first layer of aluminum gallium nitride (AlGaN) and a second layer of gallium nitride (GaN), said layers being capable of sustaining a two-dimensional electron sheet to enable electrical current to flow, the semiconductor layers comprising a plurality of active areas on which gate contact terminals are to be set down, the active areas comprising a series of trenches and fins, the fins having different widths over each active area;
a plurality of drain contact terminals adjacent respective ones of the active areas;
a plurality of source contact terminals adjacent respective ones of the active areas; and
a plurality of gate contact terminals set down across the fins of respective ones of the active areas, such that the device comprises a plurality of AlGaN/GaN high-electron-mobility transistors (HEMTs) having different threshold voltages.

18. The device of claim 17, wherein the gate contact terminals are set down perpendicular to the fins.

19. The device of claim 17, wherein the trenches extend through the semiconductor layers past a depth at which the two-dimensional electron sheet is to be formed.

20. The device of claim 17 further including at least one isolation trench between each respective one of the HEMTs.
